(19) United States
(12) Patent Application Publication
(10) Pub. No.: US 2006/0118797 A1
(43) Pub. Date: Jun. 8, 2006

(54) Light Diffusing/Collecting Member and Surface Light Source Device Using the Same

(76) Inventors: Koichi Masuyama, Tokyo (JP); Naoya Sone, Tokyo (JP); Tatsuya Umeyama, Tokyo (JP)

Correspondence Address: CERMAK & KENEALY, LLP, 515 EAST BRADDOCK RD SUITE B, Alexandria, VA, 22314, US

(21) Appl. No.: 11/275,024

(22) Filed: Dec. 2, 2005

(30) Foreign Application Priority Data
Dec. 3, 2004 (JP) 2004-350657
Dec. 20, 2004 (JP) 2004-366980

(51) Int. Cl. H01L 33/00; G02F 1/1335

(52) U.S. Cl. 257/88; 257/98; 349/64

(57) ABSTRACT

A light diffusion/collecting member and a surface light source device can be provided with a simple configuration soas to achieve an easy assembly process and weight reduction. The surface light source device can include light sources arranged within the same plane, and a flat light diffusion/collecting member arranged above the light sources. The light diffusion/collecting member can be composed of a diffusion layer having a diffusion function, a low refractive layer, and a light collecting layer having a light collecting function. These layers can be integrally stacked in this order such that the diffusion layer is the nearest to the light sources. The low refractive layer can be made of a material with a lower refractive index than those of the materials composing the diffusion layer and the light collecting layer.

This application claims the priority benefit under 35 U.S.C. §119 of Japanese Patent Application No. 2004-350657 filed on Dec. 3, 2004 and Japanese Patent Application No. 2004-366980 filed on Dec. 20, 2004, which are both hereby incorporated in their entirety by reference.

### BACKGROUND OF THE INVENTION

1. Field of the Invention

The invention relates to a light diffusing/collecting member and a surface light source device using the same. In particular, the invention relates to a surface light source device for use in the backlight of transmissive display devices employing a liquid crystal panel and the like.

2. Description of the Related Art

A conventional transmissive display device employing a liquid crystal panel and the like utilizes a surface light source device for backlighting in order to obtain a clearer image display. In particular, a color liquid crystal panel for use in a personal computer or a liquid crystal TV set is provided with a driving circuit. This limits the open area ratio of the display device. In addition, the use of a color filter reduces the light transmittance. In order to improve the visibility of such a color liquid crystal panel, a surface light source device is often equipped as a backlight.

In general, such a surface light source device for backlighting is classified as either a side-edge type or a direct lighting type in terms of the position of the light source. A large-sized display device, for example, a large-sized TV set over the size of 20 inches, usually employs a direct lighting type surface light source device. This is because a direct lighting type surface light source device does not need a light-guide plate and is formed to be hollowed so that its weight can easily be reduced.

A conventional example of this direct lighting type is shown in FIG. 1. In this description, in order to facilitate understanding, a light source is assumed to be positioned at a lower side in the device, and the light-emitting direction is assumed to be in an upper direction unless otherwise specified. However, the present invention is not limited to a particular direction of light with respect to the drawings.

In FIG. 1, the surface light source device 1 includes at least one (four in the shown example) linear light source 2 and a reflecting surface 3 arranged below each of the linear light sources 2. Also, the light source device 1 includes a diffusion plate 4, diffusion sheet 5, and a prism sheet 6 arranged in this order above the linear light source 2 and reflecting surface 3.

One example of a linear light source 2 is a cold cathode tube. The linear light sources 2 are arranged side by side in parallel to each other at equal intervals in order to emit light from the entire light emitting surface A above the linear light sources 2.

The reflecting surface 3 serves as a diffusion reflecting surface made of, for example, a white coating or a foamed resin sheet. The reflecting surface 3 is arranged below each of the linear light sources 2 to reflect almost all the light emitted downward or sideways from the corresponding light sources 2 to the upper section, which is substantially the light emitting direction.

The diffusion plate 4 is composed of a transparent plate material with a pattern for light diffusion formed on the surface thereof, for example.

The diffusion sheet 5 is prepared by mixing a light diffusing agent with a resin, the resin serving as a base material. For example, a light diffusing agent such as calcium carbonate, titanium oxide, partial-cross linked polymer fine particles, infusible acrylic polymer elements, and silicon compound may be mixed with polycarbonate resin to form such a diffusion sheet.

The prism sheet 6 can be formed by injection molding, photo-polymerization process, or compression molding of transparent resin (for example, acrylic resin, polycarbonate resin, and the like) to have fine prisms formed on the surface of the sheet. Here, the transparent resin can transmit light at least in a visible range.

The thus formed surface light source device can operate as follows: light emitted from the respective linear light sources 2 travels in the light-emitting direction (upward in the drawing) or part of the light travels toward the reflecting surface 3 and is reflected by the same to travel in the light-emitting direction. Then, the diffusion plate 4 positioned above the light sources 2 first diffuses the light and then the diffusion sheet 5 diffuses the diffused light again. Subsequently, the diffused light is collected by the prism sheet 6 to emit the light outside in the light-emitting direction. The surface light source device 1 has a light-emitting surface A, above which a display device such as a liquid crystal panel (not shown) is positioned. Accordingly, the surface light source device 1 can backlight the display device.

In the surface light source device 1 configured as described above, the light emitted from the linear light sources 2 travels through the diffusion plate 4, the diffusion sheet 5, and the prism sheet 6. By diffusing and collecting light, a backlight with substantially uniform luminance can be obtained.

A liquid crystal display device having another conventional type of backlighting device is disclosed in Japanese Patent Laid-Open Publication No. Hei 11-2813, the disclosure of which is hereby incorporated by reference. The disclosed backlighting device includes a plurality of linear light sources arranged parallel to one another. Semi-cylindrical reflectors are arranged below the respective linear light sources. A diffusion plate is arranged above the light sources, and an optical film is also arranged above the light sources and has a function of diffusing or collecting light.

Each of the linear light sources is integrated with the corresponding reflector and slidably attached to the backlighting device in the longitudinal direction of the linear light source. Thus, the respective integrated linear light sources can be detached freely, thereby facilitating the replacement of the linear light sources.

Still another conventional type of lighting device is disclosed in Japanese Patent Laid-Open Publication No. Hei 11-223812, the disclosure of which is hereby incorporated by reference. The lighting device includes a plurality of linear light sources arranged parallel to one another, a reflector sheet arranged below the light sources, a diffusion plate arranged above the light sources, and a diffusion sheet and/or a prism sheet arranged above the diffusion plate.

In this configuration, there is a gap above the diffusion plate. An alternative example is configured to require that the diffusion plate be in contact with the diffusion sheet/prism sheet while the other surface of the diffusion plate is in contact with a light transmitting sheet. Sandwiching the diffusion plate with air or other plates/sheets can reduce the temperature and/or humidity variations at both surfaces of the diffusion plate, thereby preventing the diffusion plate from being deformed due to the temperature and/or humidity variations (otherwise the diffusion plate may be deformed convexly or concavely). In other words, the prevention of the deformation of the diffusion plate can suppress luminous unevenness.

The conventional surface light source device 1 as shown in FIG. 1 needs the diffusion plate 4 and the diffusion sheet 5 in order to sufficiently diffuse light from the linear light sources 2 and obtain uniform luminance. Furthermore, the device needs the prism sheet 6 in order to improve the luminance. Namely, it is necessary to arrange the diffusion plate 4, diffusion sheet 5, and prism sheet 6 in this order above the linear light sources 2 of the conventional device 1. Accordingly, the number of parts is large and the assembly process is complicated, thereby resulting in relatively high cost.

In case of a backlighting device for a large-sized display device, the total weight of the device is also increased due to the increased number of parts, which conflicts with weight reduction requirements.

The backlighting device disclosed in Japanese Patent Laid-Open Publication No. Hei 11-2831 requires an optical sheet arranged above the diffusion plate. The provision of the optical sheet above the diffusion sheet still has the problem of requiring an increased number of parts.

The lighting device disclosed in Japanese Patent Laid-Open Publication No. Hei 11-223812 has the diffusion sheet and/or the prism sheet arranged above or in contact with the diffusion plate to prevent the diffusion plate from being deformed. This also creates the problem of requiring a large number of parts.

Accordingly, the lighting devices as shown in Japanese Patent Laid-Open Publications Nos. Hei 11-2813 and 11-223812 have a large number of parts and the assembly processes therefore are thus complicated. Due to these points, the cost will rise and also the weight of the device increases.

Note that the technique as disclosed in Japanese Patent Laid-Open Publication No. Hei 11-223812 provides the arrangement of the diffusion sheet and/or the prism sheet, which are located above the diffusion plate, with a gap therebetween. The purpose of this arrangement is to make the upper surface and the lower surface of the diffusion sheet such that it is surrounded by the same environmental condition, thereby preventing the deformation of the diffusion plate due to temperature or humidity variation.

Other configurations can be conceived, and include, for example, a configuration in which an optical film or a diffusion sheet and/or a prism sheet is(are) adhered to a diffusion plate, a configuration in which a double-layer structure optical sheet is integrally formed from a diffusion layer and a prism layer using respective materials, each having almost the same refractive index, and the like. According to these configurations, however, the light-collecting function of a prism may be suppressed. As a result, the provision of a prism-shape structure to the diffusion plate/layer can become meaningless.

In order to improve the light-collecting function, one measure is to reduce the amount of the light diffusing agent contained in the diffusion layer. This causes, however, a decrease in the performance of the diffusion function.

### SUMMARY OF THE INVENTION

According to an aspect of the invention, a light diffusing/collecting member and a surface light source device can be provided that have a simple configuration that allows easy assembly with reduced weight.

According to another aspect of the invention, a flat light diffusing/collecting member can be provided that is to be arranged above a light source. The light diffusing/collecting member can include: a diffusion layer having a light diffusing function, a low refractive layer, and a light collecting layer having a light collecting function. These layers can be integrally layered in this order with the diffusion layer being positioned nearest to the light source. In this configuration, the low refractive layer can be formed of a material having a lower refractive index than those of materials composing the diffusion layer and the light collecting layer.

In the above-described member, light emitted from a light source arranged below the member is incident on the diffusion layer. This incident light can be consistently diffused by this diffusion layer. Then, the diffused light enters the low refractive layer provided above the diffusion layer, thereby being refracted in such a direction that the outgoing angle of light becomes larger than the incident angle of light. This action can complement the diffusion function of the diffusion layer.

Then, the light passing through the low refractive layer may enter the light collecting layer at a relatively large angle, similar to the above case, thereby complementing the light collecting function.

Accordingly, the light diffusing/collecting member can be formed by sandwiching a low refractive layer with a diffusion layer and a light collecting layer as a single unit and, thus, the light diffusing/collecting member is more certain to have the diffusion function and the light collecting function, which have only been achieved in the conventional art by use of separate members. This can reduce the number of parts as well as facilitate the assembly process, thereby reducing both the parts cost and the assembly cost.

Since it is possible for this single light diffusion/collecting member to have the functions described above, a surface light source incorporating this light diffusion/collecting member can also be fabricated with a simple assembly process by simply arranging this member above a light source. Thus, the number of parts constituting the surface light source device can be reduced and the assembly can be more easily facilitated, thereby achieving cost reduction in terms of parts as well as assembly. Furthermore, this configuration can contribute to the reduction of the entire weight of the surface light source device, which is another possible advantage over the conventional technology.

In the above-described light diffusion/collecting member, the low refractive layer may be formed of a medium having a lower refractive index than those of materials composing the diffusion layer and the light collecting layer. This medium may be transparent at least in a visible region. Examples of the transparent medium for the low refractive layer include resins, glass, liquids, fluids, gasses, and air, but the invention is not limited thereto in any way.

In the above-described light diffusion/collecting member, the low refractive layer can be a hollow space portion hermetically sealed and defined by the diffusion layer and the light collecting layer, namely, the low refractive layer can be made of air or other gasses and fluids. This can facilitate the assembly of the three layer-structure member with reduced cost due to less material used.

According to still another aspect of the invention, a flat light diffusing/collecting member can be provided that is to be arranged above a light source. The light diffusing/collecting member can include: a diffusion layer having a light diffusing function, a low refractive layer, and a light collecting layer having a light collecting function. These layers can be integrally layered in this order with the diffusion layer being positioned nearest to the light source. In this configuration, the low refractive layer is configured by arranging the diffusion layer and the light collecting layer with a predetermined distance therebetween.

In this aspect, light emitted from a light source positioned below enters the diffusion layer and then enters the low refractive layer that is formed by separately arranging the diffusion layer and the light collecting layer away from each other. The light, having entered the low refractive layer, is refracted in such a direction that the outgoing angle of light becomes larger than the incident angle of light due to the difference in the refractive index. This action can complement the diffusion function of the diffusion layer.

Then, the light passing through the low refractive layer may enter the light collecting layer at a relatively large angle, similar to the above case, thereby complementing the light collecting function.

Accordingly, the light diffusing/collecting member can be formed by defining a low refractive layer with a diffusion layer and a light collecting layer as a single part and, thus, the light diffusing/collecting member can consistently provide the diffusion function and the light collecting function, which have been achieved in the conventional art by the separate members. This makes it possible to reduce the number of parts as well as facilitate the assembly process, thereby reducing both the parts cost and the assembly cost.

Since this single light diffusion/collecting member can have both the functions described above, a surface light source incorporating this light diffusion/collecting member can also be fabricated with a simple assembly process by simply arranging this member above a light source. Thus, the number of parts constituting the surface light source device can be reduced and the assembly can be facilitated, thereby achieving cost reduction in terms of parts as well as assembly. Furthermore, this configuration can contribute to the reduction of the entire weight of the surface light source device.

In the above-described light diffusion/collecting member, the low refractive layer may be configured by arranging at least one rib member between the diffusion layer and the light collecting layer to thereby separate them by a predetermined distance. The diffusion layer and the light collecting layer can be separately arranged to sandwich an air layer, or to form a hollow space structure. Accordingly, when compared with a conventional member having a diffusion plate and a light collecting sheet, the light diffusion/collecting member according to the embodiment described above can have a reduced weight if the thickness thereof is the same as that of the conventional member.

In the above-described light diffusion/collecting member, the rib member may take a plate shape, a cone shape, a columnar shape, a ball shape, or the like.

In the above-described light diffusion/collecting member, the low refractive layer may be formed simultaneously with the diffusion layer and the light collecting layer. If they are configured to be formed simultaneously, it can be formed by a co-extrusion process or other simple processes well known to those skilled in the art.

Alternatively, the low refractive layer may first be integrally formed with the diffusion layer, and thereafter it may be adhered to a separately formed light collecting layer. For example, first a rib layer and a diffusion layer can be integrally formed, and then attached to a separately prepared light collecting layer. Thereby, the diffusion layer and the light collecting layer are integrally arranged at a predetermined distance away from each other with simple assembly process.

In the light diffusion/collecting member described above, the diffusion layer may be made of a resin material composed of a base resin mixed with a light diffusing agent.

In the light diffusion/collecting member described above, the light collecting layer may be made of a resin material transparent at least in a visible region or a resin material mixed with a small amount of a light diffusing agent or a dye. Furthermore, the light collecting layer may have an optically processed shape in any one or more of its surfaces in order to impart the light collecting function.

The optically processed shape may be a prism shape which has at least one prism shape with the same cross section along a certain direction, the cross section being selected from, for example, a triangle, a trapezium, a parabola, an ellipsoid, other quadratic curves, and a combination of these cross sections, but not limited to such. Alternatively, the optically processed shape may be a surface with a number of fine polyhedron cones formed thereon, a lens array with aspheric shape, or a surface coated with spherical fine particles made of a transparent material such as a resin or glass.

According to still another aspect of the invention, a surface light source device can be provided that includes at least one light source and any one of the above-described light diffusion/collecting members arranged above the light source.

Since the above-described surface light source device utilizes the light diffusion/collecting member according to any one of the above-described aspects of the invention in combination with a light source, the number of parts can be reduced and the assembly of the device can be facilitated, thereby reducing both the parts cost and the assembly cost. In addition, since the surface light source device can have a reduced total weight, this device is suitable for use as a backlighting device for a large-sized display device.

In the above-described surface light source device, the light diffusion/collecting member may include a rib layer as described above. In this case, the rib layer may be integrally composed with the diffusion layer and a clear layer containing a small amount of a light diffusion agent or a dye, the clear layer being adhered to the separately prepared light collecting layer. In this case, first a rib layer and a diffusion layer can be integrally formed, and then attached to a separately prepared light collecting layer. Thereby, the diffusion layer and the light collecting layer are integrally arranged at a predetermined distance away from each other by means of a simple assembly process. Furthermore, because of the clear layer, the light collecting layer can be securely fixed thereto.

In the above-described surface light source device, a reflector can be provided below the light source to reflect light from the light source to a light-emitting direction. In this case, part of light emitted sideways or downward from the light source can be reflected by the reflector. Thus, that portion of light directed in the light-emitting direction can be utilized as effective light, to improve the light utilization efficiency as well as to increase luminance of the device.

As described above, a diffusion plate and an optical member having a diffusion function and a light collecting function can be integrally formed as a single part. This configuration can reduce the parts cost as well as the assembly cost. When a surface light source device is assembled with the use of this light diffusion/collecting member in combination with a light source, the device can consistently provide the diffusion function and the light collecting function while the parts cost and the assembly cost can be reduced. Furthermore, weight reduction can be achieved. The surface light source device is also suitable for, among other things, use as a backlighting device for a large-sized display device.

### BRIEF DESCRIPTION OF THE DRAWINGS

These and other characteristics, features, and advantages of the invention will become clear from the following description with reference to the accompanying drawings, wherein:

FIG. 1 is a schematic cross-sectional view showing one exemplary configuration of a conventional surface light source device;

FIG. 2 is a schematic cross-sectional view showing a configuration of a surface light source device according to an exemplary embodiment of the invention;

FIG. 3 is a schematic perspective view of the surface light source device of FIG. 2;

FIG. 4 is a cross-sectional view showing the light diffusion/collecting member used in the surface light source device of FIG. 2;

FIG. 5 is a schematic cross-sectional view showing a configuration of a surface light source device according to another exemplary embodiment of the invention;

FIG. 6 is a schematic perspective view of the surface light source device of FIG. 5; and

FIG. 7 is a cross-sectional view showing the light diffusion/collecting member used in the surface light source device of FIG. 5.

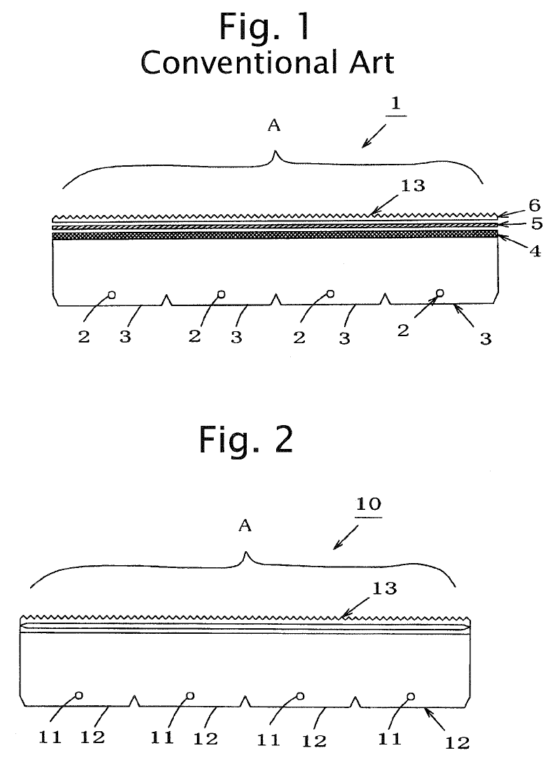

### DETAILED DESCRIPTION OF PREFERRED EMBODIMENTS

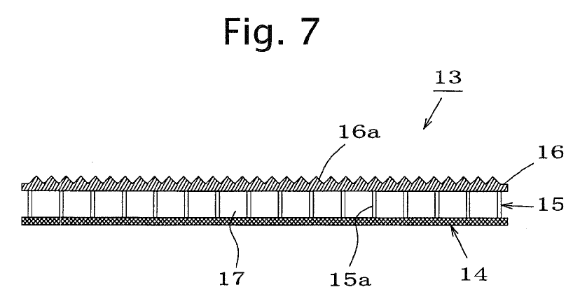

Exemplary embodiments of the invention will now be described in detail, with reference to FIGS. 2 to 7 (the same or similar components are labeled with the same reference numerals). The exemplary embodiments to be described hereinafter are examples of the invention, and various technical features are imposed thereon. However, the scope of the invention is not limited to the exemplary embodiments.

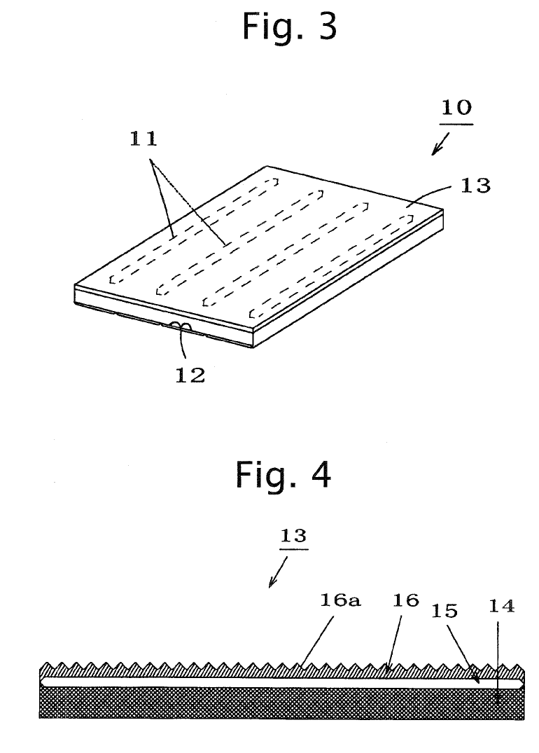

FIGS. 2 and 3 show the configuration of a surface light source according to an exemplary embodiment of the invention.

In FIGS. 2 and 3, the surface light source device 10 can include at least one linear light source 11 (four in the shown example), a reflector 12 arranged below each of the linear light sources 11, a light diffusion/collecting member 13 arranged above the light source 11 and the reflector 12.

In this exemplary embodiment, the linear light source 11 can be a cold cathode lamp. However, other light sources can be used, such as semiconductor light emitting devices, fluorescent lights, incandescent lights, etc. In order to emit light from substantially the entire upper light emitting surface A, the four linear light sources 11 can be parallel to each other at a substantially equal interval and arranged within substantially the same plane. This exemplary embodiment can employ a linear light source, but the invention is not limited thereto. For example, various other exemplary embodiments can employ various light sources such as a point light source (such as LEDs), a linear light source composed of a plurality of point light sources arranged within the same plane in line, and a surface light source composed of a plurality of point light sources arranged within a same plane in a matrix or arranged randomly.

The reflector 12 can be configured as a white coating or a foamed resin sheet, for example, to serve as a diffusion reflecting surface. The reflectors 12 can be arranged below the corresponding linear light sources 11 to reflect light emitted from the light source 11 downward or sideways to the upper direction or the light-emitting direction.

The light diffusion/collecting member 13 can be of a three-layered structure as shown in FIG. 4, composed of a diffusion layer 14, a low refractive layer 15, and a light collecting layer 16, in this order from the light source side.

The diffusion layer 14 can be composed of a resin material that is prepared by mixing a light diffusion agent with a base, to have a diffusion function. In reality, the resin material may be, for example, prepared by mixing a cross-linked methyl polymethacrylate fine particle with a transparent polycarbonate resin as a base. However, the invention is not limited thereto.

The light collecting layer 16 can be composed of a resin material which is transparent at least in a visible region. The upper and/or lower surface of the light collecting layer 16 may be provided with an optically processed shape 16a (the upper surface in the shown example).

The optically processed shape 16a may be a prism shape which has at least one prism shape with the same cross section along a certain direction, the cross section being selected from, for example, a triangle, a trapezium, a parabola, an ellipsoid, other quadratic curves, and a combination of these cross sections, but not limited to such. Alternatively, the optically processed shape 16a may be a surface with a number of fine polyhedron cones formed thereon, a lens array with aspheric shape, or a surface coated with spherical fine particles made of a transparent material such as a resin or glass.

The low refractive layer 15 can be formed of a medium having a lower refractive index than those of materials composing the diffusion layer 14 and the light collecting layer 16. In addition, the medium for the low refractive layer 15 is transparent at least in a visible region. Some examples of the media include air, or the like. In the shown example, the low refractive layer 15 is composed of a hermetically sealed hollow portion defined by the diffusion layer 14 and the light collecting layer 16.

Such a three-layered light diffusion/collecting member can be molded, for example, by gas assisted-injection molding, two-color molding, or die slide molding. As shown in the drawing, the hermetically sealed hollow portion defined by the diffusion layer 14 and the light collecting layer 16 is easily formed as a low refractive layer 15 by any of the above molding methods.

The surface light source device 10 according to the first exemplary embodiment is configured as described above and can operate as follows. When power is fed from an external power source to the respective linear light sources 11 of the device 10, the light sources 11 emit light. The emitted light is incident on the light diffusion/collecting member 13 directly or after being reflected by the reflectors 12.

The incident light is first diffused by the diffusion layer 14. Then, the diffused light enters the low refractive layer 15. At that time, since the light exits from the light diffusion layer 14 and enters the low refractive layer 15 made of a medium having a low refractive index, the light is refracted in such a direction that the outgoing angle of light becomes larger than the incident angle of light. This action complements the diffusion effect of the diffusion layer 14.

Then, the light passing through the low refractive layer 15 enters the light collecting layer 16 at a relatively large angle similar to the above case, and further is collected by the optically processed shape 16a of the light collecting layer 16. The thus collected light can be emitted above the outermost surface. The action between the low refractive layer 15 and the light collecting layer 16 can complement the light collecting function.

Accordingly, a display device (not shown) such as a liquid crystal panel located above the light emitting surface A can be backlit.

The surface light source device 10 can emit light from the linear light sources 11 which have been diffused sufficiently and collected by the light diffusion/collecting member 13. As a result, a backlight can be obtained which is substantially entirely uniform and has high luminance.

Thus, the light emitted from the linear light source 11 can be diffused and collected by a single part, or the light diffusion/collecting member 13. This reduces the number of parts constituting the surface light source device 10 as well as facilitates its assembly process, thereby reducing both the parts cost and the assembly cost. In addition, since the surface light source device 10 can have a reduced total weight because it incorporates a reduced-weight light diffusion/collecting member 13, the device is suitable for use as a backlighting device for a large-sized display device which has a weight reduction requirement.

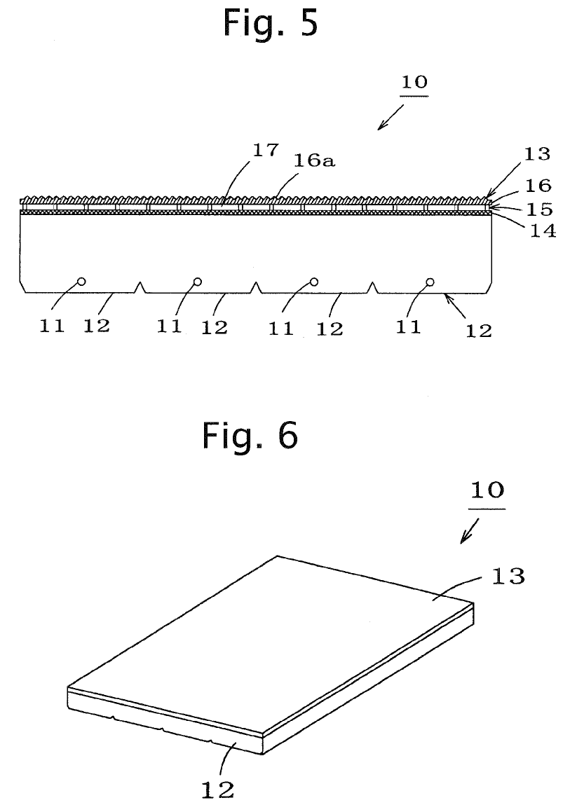

Next, another exemplary embodiment will be described with reference to FIGS. 5 to 7.

This second exemplary embodiment can have almost the same configuration as that of the first exemplary embodiment. Namely, the surface light source device 10 can include at least one linear light source 11 (four in the shown example), a reflector 12 arranged below each of the linear light sources 11, and a light diffusion/collecting member 13 arranged above the light source 11 and the reflector 12. Since the configurations of the linear light source 11 and the reflector 12 in this exemplary embodiment can be substantially the same as in the first exemplary embodiment, the description thereof is omitted.

In the present exemplary embodiment, the light diffusion/collecting member 13 can be a three-layered structure as shown in FIG. 5 and can be composed of a diffusion layer 14, a low refractive layer 15 (hereinafter, also referred to as “rib layer”), and a light collecting layer 16 in this order from the light source side. Since the configurations of the diffusion layer 14 and the light collecting layer 16 in this exemplary embodiment can be substantially the same as in the first exemplary embodiment, the description thereof is omitted.

In the present exemplary embodiment, the low refractive layer 15 can be configured by arranging a plurality of ribs 15a between the diffusion layer 14 and the light collecting layer 16 to separate them by a predetermined distance, thereby defining a space layer 17 therebetween which serves as the low refractive layer 15. In this case, the plurality of ribs 15a may be dispersed appropriately. However, if a single rib can ensure integrity of the space layer 17, the device 10 may employ a single rib.

In the present exemplary embodiment, the rib 15a may be composed of a resin material in the shape of a plate, cone, column, or the like which is integrated or otherwise connected with the diffusion layer 14 and/or the light collecting layer 16. In a modified embodiment, balls made of a resin material may be interposed between the diffusion layer 14 and the light collecting layer 16 to separate them by a predetermined distance.

The three-layered structure of the light diffusion/collecting member 13 can be formed by a common extrusion molding method, for example, to integrally mold the rib layer 15 with the diffusion layer 14 and the light collecting layer 16.

Alternatively, the rib layer 15 can integrally be molded with the diffusion layer 14 by co-extrusion molding or the like, and then adhered to the separately molded light collecting layer 16 by UV curable method.

After the rib layer 15 is integrally molded with the diffusion layer 14 and a clear layer (not show) containing a small amount of a light diffusion agent or a dye, a separately molded light collecting layer 16 can be adhered to the clear layer. In this case, the light collecting layer 16 can be securely fixed to the clear layer, to enhance the attaching strength thereof.

In the surface light source device 10 configured as described above, the light incident on the light diffusion/collecting member 13 is first diffused by passing through the diffusion layer 14. Then, the diffused light from the diffusion layer 14 enters the space layer 17 (namely, the low refractive layer 15, or the rib layer 15) which is defined by the diffusion layer 14 and the light collecting layer 16 with the rib(s) 15a interposed therebetween.

At that time, the diffused light from the diffusion layer 14 enters the space layer 17 or the low refractive layer 15 composed of a medium with a low refractive index, thereby being refracted in such a direction that the outgoing angle of light becomes larger than the incident angle of light. This action can complement the diffusion function of the diffusion layer 14.

Furthermore, the light entering the light collecting layer 16 is collected by the optically processed shape 16a of the layer 16, followed by emitting the collected light from the upper surface of the light collecting layer 16.

In the above-described exemplary embodiments, the light collecting layer 16 of the light diffusion/collecting member 13 can include an optically processed shape 16a formed on the upper surface thereof. However, the invention is not limited thereto. The optically processed shape 16a may be formed on either one or both of the upper and lower surfaces.

In the above-described exemplary embodiments, the low refractive layer 15 can be composed of a hollow area containing air. However, according to the principle of the invention the low refractive layer 15 may be composed of an appropriate medium such as a gas, a liquid, or a solid material with the proviso described above.

Accordingly, a light diffusion/collecting member and a surface light source device can be provided with a simple configuration. Thus, easy assembly processes and weight reduction can be achieved.

Such a surface light source device can be applied to a backlighting device for a liquid crystal panel display, a backlighting device for a printed translucent advertising display, a lighting device for a desktop spotlight, etc.

While there has been described what are at present considered to be preferred embodiments of the invention, it will be understood that various modifications may be made thereto, and it is intended that the appended claims cover all such modifications as fall within the true spirit and scope of the invention. Any related art references described above are hereby incorporated in there entirety by reference.

What is claimed is:

1. A light diffusing/collecting member that is configured to be arranged above a light source, the light diffusing/collecting member comprising:
a diffusion layer having an index of refraction and configured to diffuse light,
a low refractive layer having an index of refraction, and
a light collecting layer having an index of refraction and configured to collect light, the low refractive layer located between the diffusion layer and the light collecting layer, and the diffusion layer configured to be nearest to the light source, wherein
the low refractive layer is formed of a material having a refractive index lower than the refractive index of the diffusion layer and the refractive index of the light collecting layer.

2. The light diffusion/collecting member according to claim 1, wherein the low refractive layer is formed of a medium having a lower refractive index than those of the materials composing the diffusion layer and the light collecting layer, and the medium is transparent at least in a visible region.

3. The light diffusion/collecting member according to claim 1, wherein the low refractive layer is a hollow space portion hermetically sealed and defined by the diffusion layer and the light collecting layer.

4. The light diffusion/collecting member according to claim 2, wherein the low refractive layer is a hollow space portion hermetically sealed and defined by the diffusion layer and the light collecting layer.

5. A light diffusing/collecting member that is configured to be arranged above a light source, the light diffusing/collecting member comprising:
a diffusion layer configured to diffuse light,
a low refractive layer, and
a light collecting layer configured to collect light, the low refractive layer located between the diffusion layer and the light collecting layer, and the diffusion layer configured to be positioned nearest to the light source, wherein
the low refractive layer is configured by arranging the diffusion layer and the light collecting layer with a predetermined distance therebetween.

6. The light diffusion/collecting member according to claim 5, wherein the low refractive layer includes at least one rib member between the diffusion layer and the light collecting layer to thereby separate them by the predetermined distance.

7. The light diffusion/collecting member according to claim 6, wherein the rib member is selected from the group consisting of a plate shape, a cone shape, a columnar shape, and a ball shape.

8. The light diffusion/collecting member according to claim 1, wherein the low refractive layer is formed simultaneously with the diffusion layer and the light collecting layer.

9. The light diffusion/collecting member according to claim 1, wherein the low refractive layer is formed integrally with the diffusion layer and the light collecting layer.

10. The light diffusion/collecting member according to claim 5, wherein the low refractive layer is formed simultaneously with the diffusion layer and the light collecting layer.

11. The light diffusion/collecting member according to claim 5, wherein the low refractive layer is formed integrally with the diffusion layer and the light collecting layer.

12. The light diffusion/collecting member according to claim 7, wherein the low refractive layer is formed simultaneously with the diffusion layer and the light collecting layer.

13. The light diffusion/collecting member according to claim 5, wherein the low refractive layer is integrally formed with the diffusion layer, and is adhered to the light collecting layer which is separately formed.

14. The light diffusion/collecting member according to claim 1, wherein the diffusion layer is made of a resin material composed of a base mixed with a light diffusing agent.

15. The light diffusion/collecting member according to claim 5, wherein the diffusion layer is made of a resin material composed of a base mixed with a light diffusing agent.

16. The light diffusion/collecting member according to claim 1, wherein:
the light collecting layer is made of one of; a resin material transparent at least in a visible region; a resin material mixed with a light diffusing agent; and, a resin material mixed with a dye; and
the light collecting layer has a surface that includes an optically processed shape configured to collect light.

17. The light diffusion/collecting member according to claim 5, wherein:
the light collecting layer is made of one of; a resin material transparent at least in a visible region; a resin material mixed with a light diffusing agent; and, a resin material mixed with a dye; and
the light collecting layer has a surface that includes an optically processed shape configured to collect light.

18. A surface light source device comprising:
at least one light source; and
the light diffusion/collecting member according to claim 1, the member being arranged above the light source.

19. A surface light source device comprising:
at least one light source; and
the light diffusion/collecting member according to claim 5, the member being arranged above the light source.

20. The light diffusion/collecting member according to claim 1, wherein the low refractive layer is a hollow space portion defined by the diffusion layer and the light collecting layer.

21. The light diffusion/collecting member according to claim 1, wherein the low refractive layer is a fluid located between the diffusion layer and the light collecting layer.

22. The light diffusion/collecting member according to claim 5, wherein the low refractive layer includes a hollow space portion defined by the diffusion layer and the light collecting layer.

23. The light diffusion/collecting member according to claim 5, wherein the low refractive layer includes a fluid located between the diffusion layer and the light collecting layer.

24. The light diffusion/collecting member according to claim 1, wherein the light diffusion/collecting member is substantially flat.

25. The light diffusion/collecting member according to claim 5, wherein the light diffusion/collecting member is substantially flat.
